(19) United States
(12) Patent Application Publication
(10) Pub. No.: US 2022/0059170 A1
(43) Pub. Date: Feb. 24, 2022

(54) NON-VOLATILE MEMORY AND OPERATION METHOD THEREOF

(71) Applicant: Gigadevice Semiconductor (Beijing) Inc., Beijing (CN)

(72) Inventor: Minyi Chen, Beijing (CN)

(73) Assignee: Gigadevice Semiconductor (Beijing) Inc., Beijing (CN)

(21) Appl. No.: 16/952,125

(22) Filed: Nov. 19, 2020

(30) Foreign Application Priority Data
Aug. 24, 2020 (CN) 202010857889.0

(51) Int. Cl. G11C 16/16; G11C 16/26; G11C 16/30; G11C 16/34; G11C 7/10

(52) U.S. Cl. CPC G11C 16/16; G11C 16/26; G11C 7/1057; G11C 16/3472; G11C 7/1084; G11C 16/30

(57) ABSTRACT

A non-volatile memory includes: a plurality of user data storage blocks configured to store user data; a user setting storage block configured to store a bad block address table; and a controller configured to perform: executing a first erase operation on one of the plurality of user data storage blocks according to an external instruction; executing a second erase operation on the one of the plurality of user data storage blocks in response to failure of the first erase operation; marking the one of the plurality of user data storage blocks as a bad block in response to failure of the second erase operation; and updating the bad block address table stored in the user setting storage block according to the bad block newly marked. An operation method of the non-volatile memory is also provided.

### RELATED APPLICATION

This application claims the benefit of priority of Chinese Patent Application No. 202010857889.0 filed on Aug. 24, 2020, the contents of which are incorporated herein by reference in their entirety.

### FIELD AND BACKGROUND OF THE INVENTION

The present disclosure relates to the memory technical field, and more particularly to a non-volatile memory and an operation method thereof.

A NAND flash memory is a type of non-volatile memories. A bad block or blocks are checked before the NAND flash memory leaves the factory. A bad block address table is generated according to an address or addresses of the bad block or blocks. The bad block address table is stored in a read only memory (ROM).

In the prior art, updating information of the bad block or blocks is executed by a backstage. The updating information of the bad block or blocks is not executed in real time. Consequently, there is a need to solve the above-mentioned problem in the prior art.

### SUMMARY OF THE INVENTION

An objective of the present disclosure is to provide a non-volatile memory and an operation method thereof capable of solving the problem in the prior art that the updating information of the bad block or blocks is not executed in real time.

To solve the above problems, a non-volatile memory provided by the present disclosure includes: a plurality of user data storage blocks configured to store user data; a user setting storage block configured to store a bad block address table; and a controller configured to perform: executing a first erase operation on one of the plurality of user data storage blocks according to an external instruction; verifying the first erase operation; finishing an erase work in response to success of the first erase operation; executing a second erase operation on the one of the plurality of user data storage blocks in response to failure of the first erase operation; verifying the second erase operation; finishing the erase work in response to success of the second erase operation; marking the one of the plurality of user data storage blocks as a bad block in response to failure of the second erase operation; and updating the bad block address table stored in the user setting storage block according to the bad block newly marked.

In one embodiment, the non-volatile memory further includes a page buffer. The updating the bad block address table stored in the user setting storage block according to the bad block newly marked includes: reading the bad block address table from the user setting storage block, and loading the bad block address table into the page buffer; writing an address of the bad block into the bad block address table in the page buffer; and programming the user setting storage block according to the bad block address table in the page buffer.

In one embodiment, the first erase operation includes a plurality of first erase pulses, and erase voltages corresponding to the first erase pulses increase sequentially. The second erase operation includes a plurality of second erase pulses, and erase voltages corresponding to the second erase pulses are the same as the erase voltages corresponding to the first erase pulses.

In one embodiment, the first erase operation includes a plurality of first erase pulses, and erase voltages corresponding to the first erase pulses increase sequentially. The second erase operation includes a plurality of second erase pulses, an erase voltage corresponding to a first one of the second erase pulses is equal to or greater than an erase voltage corresponding to a last one of the first erase pulses, and erase voltages corresponding to the second erase pulses increase sequentially.

In one embodiment, the first erase operation includes a plurality of first erase pulses, and erase voltages corresponding to the first erase pulses increase sequentially. The second erase operation includes a plurality of second erase pulses, and an erase voltage corresponding to the second erase pulses is a maximum allowable erase voltage.

In one embodiment, the external instruction is generated by an end user.

In one embodiment, a write protection of the user setting storage block is accessible to an end user.

To solve the above problems, in an operation method of a non-volatile memory provided by the present disclosure, the non-volatile memory includes a plurality of user data storage blocks and a user setting storage block. The operation method of the non-volatile memory includes: receiving an external instruction; executing a first erase operation on one of the plurality of user data storage blocks according to the external instruction; verifying the first erase operation; finishing an erase work in response to success of the first erase operation; executing a second erase operation on the one of the plurality of user data storage blocks in response to failure of the first erase operation; verifying the second erase operation; finishing the erase work in response to success of the second erase operation; marking the one of the user data storage blocks as a bad block in response to failure of the second erase operation; and updating a bad block address table stored in the user setting storage block according to the bad block newly marked.

In one embodiment, the step of updating the bad block address table stored in the user setting storage block according to the bad block newly marked includes: reading the bad block address table from the user setting storage block, and loading the bad block address table into a page buffer; writing an address of the bad block into the bad block address table in the page buffer; and programming the user setting storage block according to the bad block address table in the page buffer.

In one embodiment, the first erase operation includes a plurality of first erase pulses, and erase voltages corresponding to the first erase pulses increase sequentially. The second erase operation includes a plurality of second erase pulses, and erase voltages corresponding to the second erase pulses are the same as the erase voltages corresponding to the first erase pulses.

In one embodiment, the first erase operation includes a plurality of first erase pulses, and erase voltages corresponding to the first erase pulses increase sequentially. The second erase operation includes a plurality of second erase pulses, an erase voltage corresponding to a first one of the second erase pulses is equal to or greater than an erase voltage corresponding to a last one of the first erase pulses, and erase voltages corresponding to the second erase pulses increase sequentially.

In one embodiment, the first erase operation includes a plurality of first erase pulses, and erase voltages corresponding to the first erase pulses increase sequentially. The second erase operation includes a plurality of second erase pulses, and an erase voltage corresponding to the second erase pulses is a maximum allowable erase voltage.

In one embodiment, the external instruction is generated by an end user.

In one embodiment, a write protection of the user setting storage block is accessible to an end user.

Compared to the prior art, in the non-volatile memory and the operation method of the non-volatile memory of the present disclosure, the controller can be automatically triggered to perform the second erase operation after the first erase operation fails. When the second erase operation fails, it is determined that the erased block is a bad block. The erased block is marked as a bad block. The address of the bad block is added to the bad block address table in the user setting storage block to update the bad block address table. As such, when the user's erase instruction is executed, the bad block can be found out in real time and information of the bad block can be updated.

### BRIEF DESCRIPTION OF THE SEVERAL VIEWS OF THE DRAWINGS

FIG. 1 illustrates a functional block diagram of a non-volatile memory and an electronic device in accordance with an embodiment of the present disclosure.

FIG. 2 illustrates a memory array in FIG. 1.

FIG. 3 illustrates waveform diagrams of erase voltages of the first erase operation and erase voltages of the second erase operation in accordance with an embodiment of the present disclosure.

FIG. 4 illustrates waveform diagrams of erase voltages of the first erase operation and erase voltages of the second erase operation in accordance with another embodiment of the present disclosure.

FIG. 5 illustrates waveform diagrams of erase voltages of the first erase operation and erase voltages of the second erase operation in accordance with yet another embodiment of the present disclosure.

FIG. 6 illustrates a flowchart of an operation method of a non-volatile memory in accordance with an embodiment of the present disclosure.

FIG. 7 illustrates a detailed flowchart of operation S612 in FIG. 6.

### DESCRIPTION OF SPECIFIC EMBODIMENTS OF THE INVENTION

Hereinafter, exemplary embodiments of the present disclosure will be described with reference to the accompanying drawings for illustrating specific embodiments which can be carried out by the present disclosure.

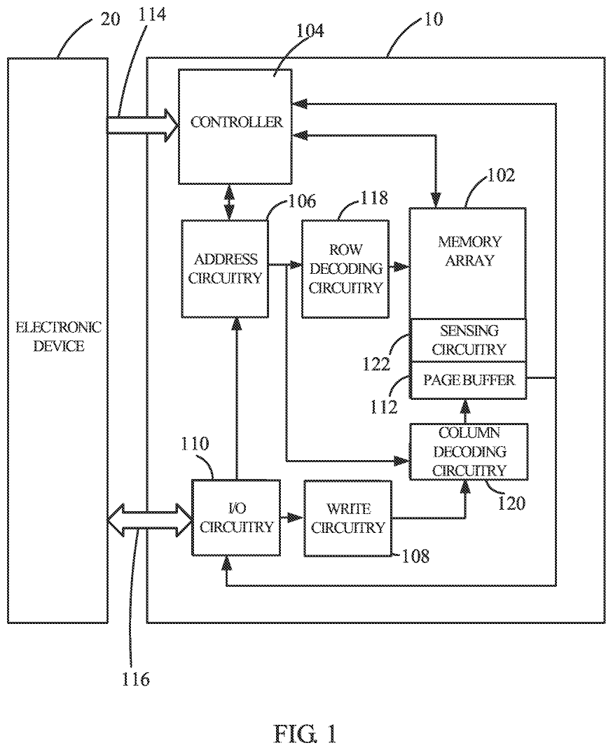

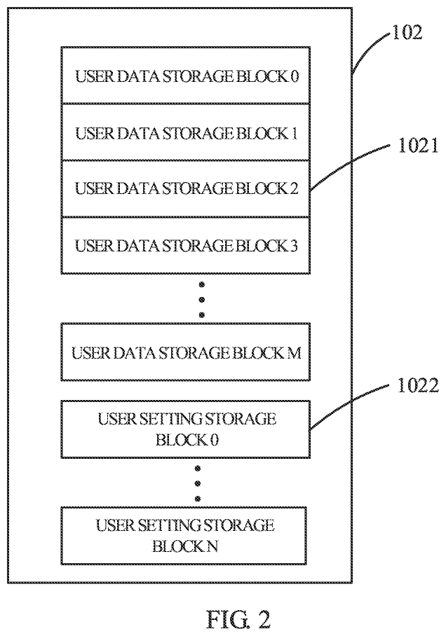

Please refer to FIG. 1 and FIG. 2. FIG. 1 illustrates a functional block diagram of a non-volatile memory 10 and an electronic device 20 in accordance with an embodiment of the present disclosure. FIG. 2 illustrates a memory array 102 in FIG. 1. The non-volatile memory 10 is an internal storage device or an external storage device of the electronic device 20.

The non-volatile memory 10 is electrically connected to the electronic device 20. The non-volatile memory 10 can perform bidirectional data communication with the electronic device 20. The non-volatile memory 10, for example, may be a universal serial bus drive, a portable storage device, or a memory card. The electronic device 20 is a user's device, for example, a mobile phone, a tablet, a notebook, or a camera. The non-volatile memory 10 can provide persistent data by retaining stored data when not powered and can include NAND flash memory, NOR flash memory, read only memory (ROM), Electrically Erasable Programmable ROM (EEPROM), Erasable Programmable ROM (EPROM), and resistance variable memory such as phase change random access memory (PCRAM), resistive random access memory (RRAM), and magnetic random access memory (MRAM), among others. The following description is made by taking the flash memory as an example.

The non-volatile memory 10 includes the memory array 102, a controller 104, an address circuitry 106, a write circuitry 108, an input/output (I/O) circuitry 110, a page buffer 112, a sensing circuitry 122, a row decoding circuitry 118, and a column decoding circuitry 120.

As shown in FIG. 2, the memory array 102 includes a plurality of blocks. Each block includes a plurality of pages. Each page includes a plurality of storage cells. Each storage cell corresponds to one or more bits. The storage cell may be implemented by a field-effect transistor including the stacked gate structure formed on a semiconductor substrate. The stacked gate structure includes a charge storage layer (a floating gate electrode) and a control gate electrode. The charge storage layer is formed on the semiconductor substrate via a gate insulating film. The control gate electrode is formed on the charge storage layer via an inter-gate insulating film. Threshold voltage changes according to the number of electrons accumulated in the charge storage layer. The storage cell is not limited to the above structure and can be the structure such as MNOS (Metal Nitride Oxide Silicon), SNOS (Silicon Nitride Oxide Semiconductor), and SONOS (Silicon Oxide Nitride Oxide Semiconductor). The blocks include a plurality of user data storage blocks 1021 and at least one user setting storage block 1022. The user data storage blocks 1021 are configured to store user data. The user setting storage block 1022 is configured to store information of a bad block (a bad block address table), a factory setting of the non-volatile memory 10, and other user settings, for example, an information setting of basic input/output system (BIOS). The non-volatile memory 10 may further includes a read-only memory (ROM) which also stores the factory setting.

The controller 104 is configured to decode an instruction which the electronic device 20 transmits via a control bus 114, execute the instruction of the electronic device 20, and/or access the memory array 102. The instruction is configured to execute an operation on the memory array 102. The operation at least includes a read operation, a write operation, an erase operation, or one other operation.

The controller 104 includes a flash translation layer (FTL) running therein. The flash translation layer is configured to manage the user data storage blocks. Furthermore, the flash translation layer is further configured for managing a logical-physical address conversion, a wear-leveling algorithm, and a garbage collection.

The address circuitry 106 is configured to latch address signals from the input/output circuitry 110 and decode the address signals to access the memory array 102. The electronic device 20 is configured to transmit the address signals to the input/output circuitry 110 via a data bus 116. The row decoding circuitry 118 is configured to select a word line based on the address signals, and the column decoding circuitry 120 is configured to select a bit line based on the address signals.

The write circuitry 108 is configured to execute a write operation on the memory array 102. The sensing circuitry 122 is configured to execute a read operation on the memory array 102.

The page buffer 112 is configured to store data read from the memory array 102 and store data to be written into the memory array 102. FIG. 1 only provides basic understanding of characteristics of the non-volatile memory 10 to simplify a circuit configuration and composition of the non-volatile memory 10 but does not limit the present disclosure.

In the prior art, when the non-volatile memory 10 is not used by an end user, the controller 104 detects the blocks 104 one by one to find out a bad block and updates the bad block information. In detail, when the non-volatile memory 10 is used by the end user, the controller 104 cannot update the bad block information. When an end user's instruction executed by the non-volatile memory 10 of the present disclosure fails, the end user's instruction is executed again. When the end user's instruction fails again, the block is determined as a bad block and the bad block information is updated. The process of updating the bad block information by executing an external instruction will be described as follows.

Please refer to FIG. 1 and FIG. 2. The controller 104 receives an external instruction (for example, the external instruction is an erase instruction and corresponds to an erase work) and executes a first erase operation on one of the user data storage blocks 1021 according to the external instruction. The external instruction is generated by an end user. The non-volatile memory 10 of the present disclosure can update the bad block information automatically by executing the external instruction. In the present embodiment, the external instruction may be but not limited to an erase instruction.

The controller 104 verifies the first erase operation. In detail, the controller 104 verifies whether the first erase operation is successful. Specifically, the verifying operation determines a number of the storage cells in the erased block which are erased unsuccessfully. When the number of the storage cells in the erased block which are erased unsuccessfully is smaller than a threshold number, it is determined that the erase operation is successful.

In response to success of the first erase operation, the controller 104 finishes the erase work. When the first erase operation is successful, it represents that the erased block is not a bad block. As such, it is not required to update the bad block address table.

In response to failure of the first erase operation, the controller 104 executes a second erase operation on the one of the user data storage blocks 1021. When the first erase operation fails, it represents that the erased block might be a bad block. A feature of the present disclosure is that the controller 104 is automatically triggered to perform a second erase operation on the block in which the first erase operation fails, thereby determining whether the erased block is a bad block. Optionally, a threshold number used in the second erase operation is smaller than the threshold number used in the first erase operation. Alternatively, the threshold number used in the second erase operation is 0. That is, it is determined that the second erase operation fails only when the number of the storage cells in the erased block which are erased unsuccessfully is 0.

The controller 104 verifies the second erase operation. In detail, the controller 104 verifies whether the second erase operation is successful.

In response to success of the second erase operation, the controller 104 finishes the erase work. When the second erase operation is successful, it represents that the erased block is not a bad block. As such, it is not required to update the bad block address table.

In response to failure of the second erase operation, the controller 104 marks the one of the user data storage blocks 1021 as a bad block. When the second erase operation fails, it represents that the erased block is a bad block. Accordingly, the erased block is marked as the bad block.

The controller 104 updates the bad block address table stored in the user setting storage block 1022 according to the bad block newly marked. In detail, the controller 104 reads the bad block address table from the user setting storage block 1022 and loads the bad block address table into the page buffer 112. Then, the controller 104 writes (adds) an address of the bad block into the bad block address table in the page buffer 112. Finally, the controller 104 programs the user setting storage block 1022 according to the bad block address table in the page buffer 112.

It is noted that the end user can change a protection code of the user setting storage block. In detail, a write protection of the user setting storage block 1022 is accessible to the end user.

In the non-volatile memory 10 of the present disclosure, the controller 104 can be automatically triggered to perform the second erase operation after the first erase operation fails. When the second erase operation fails, it is determined that the erased block is a bad block. The erased block is marked as a bad block. The address of the bad block is added to the bad block address table in the user setting storage block 1022 to update the bad block address table.

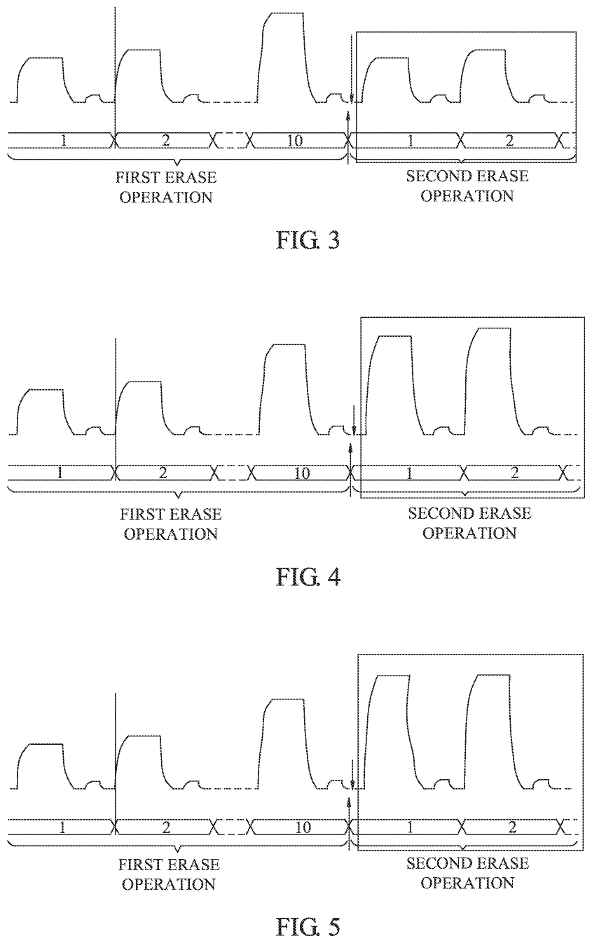

Please refer to FIG. 3. FIG. 3 illustrates waveform diagrams of erase voltages of the first erase operation and erase voltages of the second erase operation in accordance with an embodiment of the present disclosure.

As shown in FIG. 3, the first erase operation includes a plurality of first erase pulses (ten first erase pulses shown in FIG. 3). Each first erase pulse corresponds to an erase voltage and is followed by an erase verify. Erase voltages corresponding to the first erase pulses increase sequentially. In detail, the erase voltage corresponding to a second one of the first erase pulses is greater than the erase voltage corresponding to a first one of the first erase pulses. The erase voltage corresponding to a third one of the first erase pulses is greater than the erase voltage corresponding to the second one of the first erase pulses. The rest can be deduced from this.

When the first erase operation fails (i.e., the ten first erase pulses all fail), the controller 104 is automatically triggered to perform the second erase operation. The second erase operation includes a plurality of second erase pulses. Each second erase pulse corresponds to an erase voltage and is followed by an erase verify. Erase voltages corresponding to the second erase pulses are the same as the erase voltages corresponding to the first erase pulses. In detail, the erase voltage corresponding to the first one of the first erase pulses is equal to the erase voltage corresponding to a first one of the second erase pulses. The erase voltage corresponding to the second one of the first erase pulses is equal to the erase voltage corresponding to a second one of the second erase pulses. The rest can be deduced from this. As such, the erase voltages corresponding to the second erase pulses also increase sequentially.

Please refer to FIG. 4. FIG. 4 illustrates waveform diagrams of erase voltages of the first erase operation and erase voltages of the second erase operation in accordance with another embodiment of the present disclosure.

As shown in FIG. 4, the first erase operation includes a plurality of first erase pulses (ten first erase pulses shown in FIG. 4). Each first erase pulse corresponds to an erase voltage and is followed by an erase verify. Erase voltages corresponding to the first erase pulses increase sequentially. In detail, the erase voltage corresponding to a second one of the first erase pulses is greater than the erase voltage corresponding to a first one of the first erase pulses. The erase voltage corresponding to a third one of the first erase pulses is greater than the erase voltage corresponding to the second one of the first erase pulses. The rest can be deduced from this.

When the first erase operation fails (i.e., the ten first erase pulses all fail), the controller 104 is automatically triggered to perform the second erase operation. The second erase operation includes a plurality of second erase pulses. Each second erase pulse corresponds to an erase voltage and is followed by an erase verify. The erase voltage corresponding to a first one of the second erase pulses is equal to or greater than the erase voltage corresponding to a last one of the first erase pulses, and the erase voltages corresponding to the second erase pulses increase sequentially. In detail, the erase voltage corresponding to the first one of the second erase pulses is equal to or greater than the erase voltage corresponding to the last one of the first erase pulses, the erase voltage corresponding to a second one of the second erase pulses is greater than the erase voltage corresponding to the first one of the second erase pulses, and the erase voltage corresponding to a third one of the second erase pulses is greater than the erase voltage corresponding to the second one of the second erase pulses. The rest can be deduced from this.

It is noted that when the erase voltage corresponding to one of the second erase pulses reaches a maximum allowable erase voltage, the erase voltage corresponding to a next one of the second erase pulses does not increase and remains as the maximum allowable erase voltage.

Please refer to FIG. 5. FIG. 5 illustrates waveform diagrams of erase voltages of the first erase operation and erase voltages of the second erase operation in accordance with yet another embodiment of the present disclosure.

As shown in FIG. 5, the first erase operation includes a plurality of first erase pulses (ten first erase pulses shown in FIG. 5). Each first erase pulse corresponds to an erase voltage and is followed by an erase verify. Erase voltages corresponding to the first erase pulses increase sequentially. In detail, the erase voltage corresponding to a second one of the first erase pulses is greater than the erase voltage corresponding to a first one of the first erase pulses. The erase voltage corresponding to a third one of the first erase pulses is greater than the erase voltage corresponding to the second one of the first erase pulses. The rest can be deduced from this.

When the first erase operation fails (i.e., the ten first erase pulses all fail), the controller 104 is automatically triggered to perform the second erase operation. The second erase operation includes a plurality of second erase pulses. Each second erase pulse corresponds to an erase voltage and is followed by an erase verify. The erase voltage corresponding to each second erase pulse is a maximum allowable erase voltage.

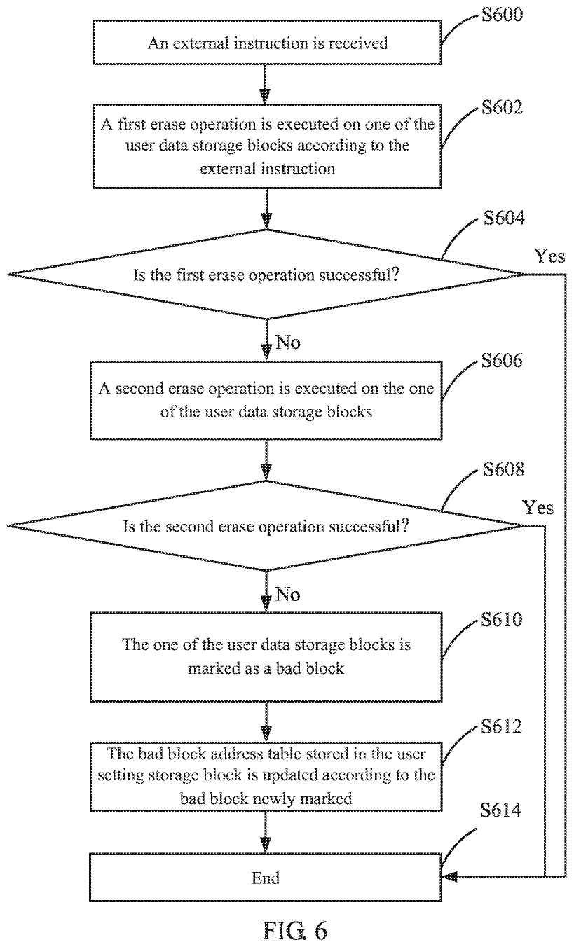

Please refer to FIG. 6. FIG. 6 illustrates a flowchart of an operation method of a non-volatile memory in accordance with an embodiment of the present disclosure.

The non-volatile memory includes a plurality of user data storage blocks and at least one user setting storage block. The operation method of the non-volatile memory includes the following operations.

In operation S600, an external instruction is received.

The external instruction (for example, the external instruction is an erase instruction and corresponds to an erase work) is generated by an end user. The non-volatile memory of the present disclosure can update a bad block address table automatically by executing the external instruction. In the present embodiment, the external instruction may be but not limited to an erase instruction.

In operation S602, a first erase operation is executed on one of the user data storage blocks according to the external instruction.

In operation S604, it is verified whether the first erase operation is successful. When the first erase operation is successful, operation S614 is performed. When the first erase operation fails, operation S606 is performed.

When the first erase operation is successful, it represents that the erased block is not a bad block. As such, it is not required to update the bad block address table. When the first erase operation fails, it represents that the erased block might be a bad block.

A feature of the present disclosure is that the controller is automatically triggered to perform a second erase operation on the block in which the first erase operation fails, thereby determining whether the erased block is a bad block.

In operation S606, a second erase operation is executed on the one of the user data storage blocks.

In operation S608, it is verified whether the second erase operation is successful. When the second erase operation is successful, operation S614 is performed. When the second erase operation fails, operation S610 is performed.

When the second erase operation is successful, it represents that the erased block is not a bad block. As such, it is not required to update the bad block address table. When the second erase operation fails, it is determined that the erased block is a bad block. As such, it is required to update the bad block address table automatically.

In operation S610, the one of the user data storage blocks is marked as a bad block.

In operation S612, the bad block address table stored in the user setting storage block is updated according to the bad block newly marked.

In operation S614, the operation method of the non-volatile memory ends.

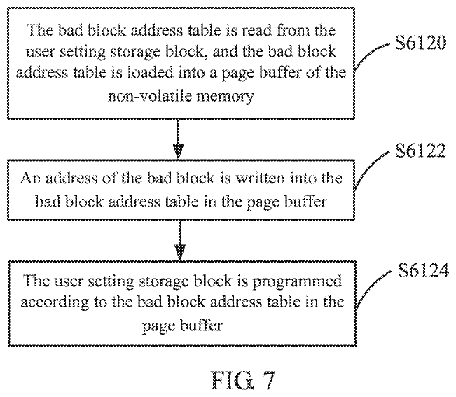

Please refer to FIG. 7. FIG. 7 illustrates a detailed flowchart of operation S612 in FIG. 6. Operation S612 includes the following operations.

In operation S6120, the bad block address table is read from the user setting storage block, and the bad block address table is loaded into a page buffer of the non-volatile memory.

In operation S6122, an address of the bad block is written into the bad block address table in the page buffer.

In operation S6124, the user setting storage block is programmed according to the bad block address table in the page buffer.

It is noted that the end user can change a protection code of the user setting storage block. In detail, a write protection of the user setting storage block is accessible to the end user.

In the operation method of the non-volatile memory, waveform diagrams of erase voltages of the first erase operation and erase voltages of the second erase operation can be referred to related description of FIG. 3 to FIG. 5 and are not repeated herein.

In the non-volatile memory and the operation method of the non-volatile memory of the present disclosure, the controller can be automatically triggered to perform the second erase operation after the first erase operation fails. When the second erase operation fails, it is determined that the erased block is a bad block. The erased block is marked as a bad block. The address of the bad block is added to the bad block address table in the user setting storage block to update the bad block address table.

In summary, although the present disclosure has been provided in the preferred embodiments described above, the foregoing preferred embodiments are not intended to limit the present disclosure. Those skilled in the art, without departing from the spirit and scope of the present disclosure, may make modifications and variations, so the scope of the protection of the present disclosure is defined by the claims.

What is claimed is:

1. A non-volatile memory, comprising:
a plurality of user data storage blocks configured to store user data;
a user setting storage block configured to store a bad block address table; and
a controller configured to perform:
executing a first erase operation on one of the plurality of user data storage blocks according to an external instruction;
verifying the first erase operation;
finishing an erase work in response to success of the first erase operation;
executing a second erase operation on the one of the plurality of user data storage blocks in response to failure of the first erase operation;
verifying the second erase operation;
finishing the erase work in response to success of the second erase operation;
marking the one of the plurality of user data storage blocks as a bad block in response to failure of the second erase operation; and
updating the bad block address table stored in the user setting storage block according to the bad block newly marked.

2. The non-volatile memory of claim 1, further comprising a page buffer, the updating the bad block address table stored in the user setting storage block according to the bad block newly marked comprising:
reading the bad block address table from the user setting storage block, and loading the bad block address table into the page buffer;
writing an address of the bad block into the bad block address table in the page buffer; and
programming the user setting storage block according to the bad block address table in the page buffer.

3. The non-volatile memory of claim 1, wherein the first erase operation comprises a plurality of first erase pulses, and erase voltages corresponding to the plurality of first erase pulses increase sequentially;
the second erase operation comprises a plurality of second erase pulses, and erase voltages corresponding to the plurality of second erase pulses are the same as the erase voltages corresponding to the plurality of first erase pulses.

4. The non-volatile memory of claim 1, wherein the first erase operation comprises a plurality of first erase pulses, and erase voltages corresponding to the plurality of first erase pulses increase sequentially;
the second erase operation comprises a plurality of second erase pulses, an erase voltage corresponding to a first one of the plurality of second erase pulses is equal to or greater than an erase voltage corresponding to a last one of the plurality of first erase pulses, and erase voltages corresponding to the plurality of second erase pulses increase sequentially.

5. The non-volatile memory of claim 1, wherein the first erase operation comprises a plurality of first erase pulses, and erase voltages corresponding to the plurality of first erase pulses increase sequentially;
the second erase operation comprises a plurality of second erase pulses, and an erase voltage corresponding to each of the plurality of second erase pulses is a maximum allowable erase voltage.

6. The non-volatile memory of claim 1, wherein the external instruction is generated by an end user.

7. The non-volatile memory of claim 1, wherein a write protection of the user setting storage block is accessible to an end user.

8. An operation method of a non-volatile memory, the non-volatile memory comprising a plurality of user data storage blocks and a user setting storage block, the operation method of the non-volatile memory comprising:
receiving an external instruction;
executing a first erase operation on one of the plurality of user data storage blocks according to the external instruction;
verifying the first erase operation;
finishing an erase work in response to success of the first erase operation;
executing a second erase operation on the one of the plurality of user data storage blocks in response to failure of the first erase operation;
verifying the second erase operation;
finishing the erase work in response to success of the second erase operation;
marking the one of the plurality of user data storage blocks as a bad block in response to failure of the second erase operation; and
updating a bad block address table stored in the user setting storage block according to the bad block newly marked.

9. The operation method of the non-volatile memory of claim 8, the step of updating the bad block address table stored in the user setting storage block according to the bad block newly marked comprising:
reading the bad block address table from the user setting storage block, and loading the bad block address table into a page buffer;
writing an address of the bad block into the bad block address table in the page buffer; and
programming the user setting storage block according to the bad block address table in the page buffer.

10. The operation method of the non-volatile memory of claim 8, wherein the first erase operation comprises a plurality of first erase pulses, and erase voltages corresponding to the plurality of first erase pulses increase sequentially;
the second erase operation comprises a plurality of second erase pulses, and erase voltages corresponding to the plurality of second erase pulses are the same as the erase voltages corresponding to the plurality of first erase pulses.

11. The operation method of the non-volatile memory of claim 8, wherein the first erase operation comprises a plurality of first erase pulses, and erase voltages corresponding to the plurality of first erase pulses increase sequentially;
the second erase operation comprises a plurality of second erase pulses, an erase voltage corresponding to a first one of the plurality of second erase pulses is equal to or greater than an erase voltage corresponding to a last one of the plurality of first erase pulses, and erase voltages corresponding to the plurality of second erase pulses increase sequentially.

12. The operation method of the non-volatile memory of claim 8, wherein the first erase operation comprises a plurality of first erase pulses, and erase voltages corresponding to the plurality of first erase pulses increase sequentially;
the second erase operation comprises a plurality of second erase pulses, and an erase voltage corresponding to each of the plurality of second erase pulses is a maximum allowable erase voltage.

13. The operation method of the non-volatile memory of claim 8, wherein the external instruction is generated by an end user.

14. The operation method of the non-volatile memory of claim 8, wherein a write protection of the user setting storage block is accessible to an end user.
